(19) United States
(12) Patent Application Publication
(10) Pub. No.: US 2011/0027994 A1
(43) Pub. Date: Feb. 3, 2011

(54) POLISHING SLURRY FOR CMP

(76) Inventors: Katsumi Mabuchi, Hitachi (JP); Haruo Akahoshi, Hitachi (JP); Yasuo Kamigata, Tsukuba (JP); Masanobu Habiro, Tsukuba (JP); Hiroshi Ono, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/900,926

(22) Filed: Oct. 8, 2010

Related U.S. Application Data
(62) Division of application No. 11/572,321, filed on Jan. 19, 2007.

(30) Foreign Application Priority Data
Sep. 14, 2004 (JP) 2004-267366

(51) Int. Cl. H01L 21/306

(52) U.S. Cl. 438/692; 257/E21.23

(57) ABSTRACT

A polishing liquid for CMP has a composition loaded with, for example, an inorganic salt, a protective film forming agent and a surfactant capable of imparting a dissolution accelerating activity to enlarge a difference between polishing speed under non-load and polishing speed under load. By virtue of this polishing liquid for CMP, there can be simultaneously accomplished a speed increase for increasing CMP productivity, and wiring planarization for miniaturization and multilayer formation of wiring.

This application is a Divisional application of prior application Ser. No. 11/572,321, filed Jan. 19, 2007, the contents of which are incorporated herein by reference in their entirety. No. 11/572,321 is a National Stage Application, filed under 35 USC 371, of International (PCT) Application No. PCT/JP2005/14878, filed Aug. 9, 2005.

### TECHNICAL FIELD

The present invention relates to a polishing liquid used for chemical mechanical polishing (CMP) particularly used in a wiring process of a semiconductor device.

### BACKGROUND ART

As a result of higher performance of LSI, there has been mainly employed so-called Damascene method as microprocessing techniques in an LSI manufacturing process, in which copper is embedded in an insulation film by way of a groove previously formed on the insulation film using an electroplating method and then copper remaining at portions other than a groove portion for forming wiring is removed by using a chemical mechanical polishing (CMP) method, thereby forming wiring. A polishing liquid generally used in the CMP contains an oxidizer and solid particles, and a protective film forming agent and a solubilizer for metal oxides or the like are added into the polishing liquid if needed. There have been known particulates made of silica, alumina, zirconia and ceria of about several ten nm as the solid particles. There have been known hydrogen peroxide, iron nitrate, potassium ferricyanide and ammonium persulfate or the like as the oxidizer.

A higher polishing speed of copper by CMP has been required for a higher productivity. The addition of a metal oxide solubilizer has been recognized to be effective as a conventional method for increasing the polishing speed. It is believed to be because the scrape effect due to the solid abrasive grain is increased by dissolving particles made of a metal oxide scraped off by the solid abrasive grain in the polishing liquid. In addition, a higher the concentration of the added oxidizer is known to be effective. Also, it has been known that the polishing speed is increased by forming a copper compound insoluble in water and a copper compound soluble in water on copper wiring, adding an amino acid, loading an iron (III) compound, and loading a polyvalent metal such as aluminum, titanium, chromium, iron, cobalt, nickel, copper, zinc, germanium, zirconium, molybdenum, tin, antimony, tantalum, tungsten, lead or cerium.

On the other hand, there occurs a problem that a dishing phenomenon in which the center of a metal wiring part is recessed like a dish occurs when increasing the polishing speed, thereby worsening flatness. In order to prevent the dishing phenomenon, a compound exhibiting an operation of surface protection is usually is added. This is because the ionization of copper due to the oxidizer is suppressed by forming a precise protective film on the surface of copper and the excess dissolution of copper into the polishing liquid is prevented. There has been generally known chelating agents including benzotriazole (BTA) as the compound exhibiting this operation.

Since a protective coating is generally formed on also a portion which should be polished when the chelating agents including BTA are added to reduce the dishing, the polishing speed is extremely reduced. In order to solve the extreme reduction of the polishing speed, various additive agents have been examined. For example, JP Patent Publication (Kokai) No. 2002-12854A discloses the addition of a compound which has a heterocycle, and sulfonate at the ratio of 1/10 to 1/0.03.

### DISCLOSURE OF THE INVENTION

In CMP, a speed increase has been required for a higher productivity. Also, the wiring planarization has been required for miniaturization and multilayer formation of wiring. However, since the higher productivity has a trade-off relation with the miniaturization and multilayer formation of wiring as described above, it is very difficult to accomplish them in parallel. Since a protective coating is generally formed on also a portion which should be polished when the chelating agents including BTA are added to reduce the dishing as described above, the polishing speed is extremely reduced. It has been also examined that the rationalization is attained by adjusting the quantities of an etching agent and chelating agent to ease the extreme reduction of the polishing speed. However, it is difficult to find out the satisfactory conditions. Although the increase in a polishing pressure is also considered in order to remove the protective film, this method is not suitable when taking into consideration that a porous low dielectric constant insulation film will become mainstream from now on. Although various additive agents and techniques for accomplishing them in parallel as described above have been also examined, a polishing liquid which satisfies all conditions such as performance, cost and user-friendliness has not been developed yet. It is an object of the present invention to (1) reduce the dishing and erosion during forming embedded wiring, (2) increase the speed of the polishing, and (3) simplify washing after CMP.

To make a flatter wiring, it is important to increase the dissolving speed of copper on a portion to which load is applied, that is, a portion of copper in contact with the pad, and to suppress the dissolving speed of copper on a portion to which the load is not applied, that is, a portion of copper which is not in contact with the pad directly.

In order to solve the above problem in consideration of this description, the polishing liquid for CMP of the present invention is comprised of a composition loaded with a metal oxidizer and an abrasive grain as a fundamental composition, a compound which dissolves copper and generates a complex with copper, a pH adjuster, a dissolution accelerator which promotes the dissolution of copper under load, and a dissolution inhibitor which suppresses the dissolution of copper under non-load.

Examples of the metal oxidizer in the present invention include a peroxide represented by hydrogen peroxide, a hypochlorous acid, a peracetic acid, a bichromic acid compound, a permanganic acid compound, a persulfuric acid compound, iron nitrate and a ferricyanide. Of these, hydrogen peroxide forming a harmless decomposition product and a persulfate represented by ammonium persulfate are desirable. The content of the oxidizer is different depending on the oxidizer to be used. For example, the content of the oxidizer is preferably about 0.5 to about 3.0 M in using the hydrogen peroxide, and is preferably about 0.05 to about 0.2 M in using the ammonium persulfate.

In the present invention, examples of compounds dissolving copper and forming a complex with copper include an inorganic acid such as phosphoric acid and an organic acid such as carboxylic acid. Examples of the carboxylic acids include: formic acid and acetic acid as monocarboxylic acid; oxalic acid, maleic acid, malonic acid and succinic acid as dicarboxylic acid; tartaric acid, citric acid and malic acid as oxycarboxylic acid; and benzoic acid and phthalic acid as aromatic carboxylic acid, and particularly, the oxycarboxylic acids are effective. In addition, amino acids, aminosulfuric acid, and salts thereof, glycine and aspartic acid are also effective. The content thereof is preferably about 0.005 M to about 0.1 M.

Examples of copper-dissolution accelerators under load in the present invention include nitrate, sulfate, thiocyanic acid salt, ammonium salt and oxo-acid salt. Particularly, potassium nitrate, ammonium nitrate, aluminium nitrate, potassium thiocyanate, potassium sulfate, ammonium perchlorate, potassium perchlorate and aluminum perchlorate are effective. The content thereof is preferably 0.01 M or more, and particularly, is most preferably about 0.1 M to about 0.2 M. Trivalent iron ions are also effectively added.

Copper-dissolution inhibitor in the present invention consists of a compound capable of forming an insoluble compound with copper and a surfactant. Examples of the compounds forming the insoluble complex with copper include a compound having a heterocyclic ring such as a triazole represented by benzotriazole, a triazole derivative, a quinaldinic acid salt and oxine, as well as benzoin oxime, anthranilic acid, salicylaldoxime, nitrosonaphthol, cupferron, haloacetic acid and cysteine. The content thereof is preferably 0.005 M to 0.1 M, and particularly most preferably about 0.02 M to about 0.05M. Examples of the surfactants used as a protective film forming agent include an anionic, cationic, amphoteric and nonionic surfactants. Since the surface potential of copper is positive in an acidic slurry, the anionic and amphoteric surfactants are particularly effective. Examples of the anionic surfactants include an alkylbenzene sulfonate and an alkylnaphthalene sulfonate both having a sulfone group, a dodecyl sulfate and alkyl ether sulfate as sulfuric ester, an oleate as carboxylic acid, a polyacrylate and an alkyl ether carboxylate. Examples of the amphoteric surfactants include higher alkyl amino acid. The cationic and nonionic surfactants are also effective. Examples of the cationic surfactants include cetylammonium bromide, alkylnaphthalene chloride pyridinium, an aliphatic amine salt and an aliphatic ammonium salt. Since bromide ions (Br⁻) which have negative charges in the cetylammonium bromide are firstly absorbed on the surface of copper and C₁₆H₃₃N(CH₃)⁴⁺ is absorbed on the portions of the negative charges, even the cationic surfactant can be absorbed in large quantity on the surface of copper as well as the anionic surfactant. Examples of the nonionic surfactants include polyoxyethylene alkyl ether, polyoxyethylene ether and polyethyleneglycol fatty ester. Of these, a dodecylbenzene sulfonic acid salt, cetyltrimethylammonium bromide, an oleate, sodium dodecyl sulfate and a polyacrylate are particularly effective. Also, in addition to the above surfactants, polymers such as polyethyleneglycol, polyacrylamide, polyvinyl alcohol and polyvinylpyrrolidone are also effectively added. The content of the surfactant is preferably 0.00001 M to 0.002 M or 0.0005 wt % to 0.05 wt %. As described later, in order to exhibit a characteristic for accomplishing both high-speed polishing and low dishing, the molarity ratio of the compound capable of forming an insoluble compound with copper to the surfactant is important. When the molar concentration of the compound capable of forming an insoluble compound is set to 1, the molar ratio of the surfactant is preferably adjusted to 0.0001 to 0.4, or the weight ratio thereof is preferably adjusted to 0.0004 to 1.0.

Furthermore, it is also effective to make a water-soluble polymer as an additive agent coexist. The addition of this water-soluble polymer can not only increase the exchange current density under load, but also decrease the exchange current density under non-load. This principle is not clear now. The water-soluble polymer includes polyacrylic acid, polyvinylpyrrolidone, polyacrylamide, polyvinyl alcohol and poly-(4-vinylpyridine), but a similar effect was also observed in other water-soluble polymers.

As the abrasive grain in the present invention, an organic abrasive grain made of polystyrene and polyacryl or the like can be used in addition to an inorganic abrasive grain made of alumina, silica, zirconia and ceria or the like. Colloidal silica and colloidal alumina having an average particle diameter of 100 nm or less are particularly preferable in view of suppressing occurrence of scratches to a low value.

The pH of the polishing liquid in the present invention is preferably 3.0 or less, and about pH 2.0 is particularly effective. Examples of the pH adjusters include sulfuric acid, nitric acid and ammonia. When the pH is 3.5, particularly, the exchange current density under load is notably reduced. It is recommend that a slurry for Cu-CMP is acid in view of the fact that a slurry for barrier generally used in barrier polishing after Cu-CMP is acid and in view of a washing process or the like.

An ethylenediamine tetraacetate, bipyridyl, quinolinic acid, glycine and a phosphonate salt which generate a water-soluble compound with copper can be also added if needed in addition to the additive agents shown above.

Hereinafter, the principle of the present invention will be described. As described above, to make the wiring flatter, it is important to increase the dissolving speed of copper in the portion to which the load is applied, that is, the portion of copper in contact with the pad and to suppress the dissolving speed of copper in the portion to which the load is not applied, that is, the portion of copper which is not in contact with the pad directly. When electrolytic copper plating is applied onto an insulation film which has a groove formed on a surface of a substrate as shown in FIG. 1A, a portion corresponding to a wiring part usually has a recessed shape. In FIG. 1B of a state carrying out the CMP, copper and the pad are not in contact with each other in the recessed wiring portion, and the pad and copper are in contact with each other in a portion other than the wiring portion. When the polishing speed of the portion which is in contact with copper is the same as the polishing speed in the portion which is not in contact with copper, the shape after polishing is the shape before polishing maintained as it is. On the other hand, when the polishing speed of the portion which is in contact with copper is slower than the polishing speed of the portion which is not in contact with copper, as shown in FIG. 1C, the depth of the hollow for the wiring portion becomes shallow with advance of polishing. Therefore, the slurry which exhibits such a characteristic can accomplish the high-speed polishing as well as the low dishing. Even if the polishing speed of copper of the portion which is not in contact with the pad is small, when the polishing speed of the portion which is in contact with the pad is slow, a longer time is required for polishing to reduce the polishing remainder of copper. The elution of copper of the portion which is not in contact with the pad meanwhile advances, and the low dishing cannot be attained.

Then, a device shown in FIG. 2 was invented to investigate the dissolving speed of copper of the portion to which the load is applied and the dissolving speed of copper of the portion to which the load is not applied in various slurries. A rotational shaft having a copper electrode is attached to a motor having a rotation control mechanism, and is pushed against the pad. A load pushed against the pad is measured using a balance, and a load applied to copper electrode is adjusted using a jack provided under the balance. The dissolving speed of copper is measured as the exchange current density by Tafel measurement using an electrochemical measurement under the presence or absence of the load in a rotary state. For the measurement of the exchange current density, there was used a platinum electrode on which copper is electroplated so that copper has a thickness of 10 to 20 μm. After polishing copper electrode in a given time before measuring the exchange current densities, the exchange current densities under load and under non-load were respectively measured.

As a result of evaluating using the measurement device, the present inventors found out a new, effective method for increasing the exchange current density when the load is applied (under the polishing conditions), in addition to a known method of increasing the concentration of the oxidizer or adding a metal oxide solubilizer. In that method, 0.01 M or more of an inorganic salt such as potassium nitrate, ammonium nitrate, aluminium nitrate, potassium thiocyanate, potassium sulfate, ammonium perchlorate, potassium perchlorate or aluminum perchlorate is added to set the total ion concentration in the system at 100 mM or more. It is believed that since the electrical conductivity of the solution is increased by adding these salts and the ions thus migrate more easily, the exchange current density is increased. These inorganic salts are characterized by inorganic salts represented by nitrate, sulfate, thiocyanate, ammonium and oxo-acid salt, and their anionic species having a oxidation potential more positive than water, and stable at the oxidation potential of water. A potential-pH diagram (for example, MARCEL POURBAY, ATRAS OF ELECTROCHEMICAL EQUILIBRIA, NATIONAL ASSOCIATION of CORROSION ENGINEERS) can confirm what kind of substance exhibits such a characteristic. For example, when compounds with different forms of S are viewed for the stable region of the potential-pH diagram for S, SO₄²⁻ at pH 2 is stable at the oxidation potential of the water and has an oxidation potential more positive than the water. However, although S₂O₈²⁻ satisfies the conditions that it has an oxidation potential more positive than the water (to say more accurately, it has the maximum oxidation number), S₂O₈²⁻ is not stable in the stable region of the water, and does not satisfy the conditions as the solubility accelerator of the present invention. Since such a substance exhibits oxidizing properties strongly, the dissolving speed (also, the polishing speed) of copper under non-load to be described later is also increased when the substance is added. Therefore, a higher solubility of copper under load and a lower solubility thereof under non-load cannot be compatible. Such a substance may be used as the oxidizer, but it is necessary to keep its concentration at a suitable level.

The exchange current density when the load is not applied was also measured by the electrochemical measurement. As a result, the present inventors found out that a method for using the compound generating the insoluble compound with copper and the surfactant together was effective in addition to a method for using copper and a chelate compound such as BTA conventionally known as a copper elution suppressing method. In addition, the present inventors found out that the optimal concentration thereof, that is, the concentration which does not reduce the exchange current density when the load is applied and reduces the exchange current density only when the load is not applied is changed according to the load.

For example, FIG. 3 shows the exchange current density in each of the loads when adding dodecylbenzene sulfonic acid salts (DBS) having various concentrations into HS-C430-A3 slurry containing a surface protection film forming agent for copper and manufactured by Hitachi Chemical Co., Ltd. When the DBS is added into the HS-C430-A3 slurry, the exchange current density under non-load cannot be reduced even if the DBS is added until the concentration of the DBS reaches a prescribed concentration. However, when a prescribed DBS or more is added, only the exchange current density under non-load can be reduced while the exchange current density under load is not reduced. However, the excessive addition of the DBS reduces also the exchange current density under load. Therefore, the optimal DBS concentration range exists, which reduces only the exchange current density under non-load and does not reduce the exchange current density under load. This can be described as follows. The surface of copper is positively charged in an acid liquid containing a compound capable of forming a copper protection film. This degree is determined according to the concentration of a copper protection film forming compound. Therefore, although, of these, the anionic surfactant is particularly effective, the addition of the surfactant brings about the absorption of the surfactant onto the surface of copper protection film to increase protective properties, thereby reducing the exchange current density under non-load. On the other hand, since this bonding force is weak, the surfactant is simply eliminated under load polishing until the concentration of the surfactant reaches a prescribed concentration, and the exchange current density is not reduced. However, since the increase in the concentration resupplies the surfactant one after another, the exchange current density under load is also reduced. The same phenomenon arises also for copper protection film forming agent. Although a protective film made of a copper-chelate compound is formed on the surface of copper under non-load, thereby preventing the corrosion of copper, this protective film is comparatively easily removed under the polishing conditions, that is, by such physical contact as occurs under load, and thereby the exchange current density is not reduced under load. However, the addition of a prescribed concentration or more increases the resupplying speed, and reduces the exchange current density also under load.

Therefore, in order to reduce the exchange current density under non-load and to increase the exchange current density under load, it is necessary to add a suitable inorganic salt and add the surface protection film forming agent and the surfactant, and the concentrations of the surface protection film forming agent and surfactant in this case are important.

In view of the pH and oxidation-reduction potential of the above polishing liquid, when the form of copper is a corrosion region of copper, that is, a region where copper ions are stable, copper can be water-soluble, and a copper insoluble compound can be efficiently generated under non-load. When the ammonia coexists, a copper ammonia complex becomes stable at pH 5 or more and at the potential of 0.3 V or more. When the ammonia does not coexist, a copper oxide becomes stable in the region. Therefore, it is important to reduce the pH so as not to generate them and add the oxidizer to increase the potential and produce an atmosphere where copper ions are stable.

The polishing liquid for CMP of the present invention is comprised of a composition loaded with, for example, an inorganic salt, a protective film forming agent and a surfactant capable of imparting a dissolution accelerating activity to enlarge a difference between the polishing speed under non-load and the polishing speed under load. By virtue of this polishing liquid for CMP, there can be accomplished both high CMP polishing speed and dishing suppression, and thereby the highly reliable wiring can be formed.

### BRIEF DESCRIPTION OF THE DRAWINGS

FIG. 1 shows a process for removing a surplus copper layer on a wiring groove formed on a silicon substrate by CMP; FIG. 1A shows a process before CMP; FIG. 1B shows a process during CMP; FIG. 1C shows a process after CMP;

FIG. 2 is a schematic view of an exchange current density measurement device under polishing load; and

FIG. 3 shows the influence of a DBS concentration on the exchange current density of copper in a slurry containing a compound capable of forming a copper insoluble compound.

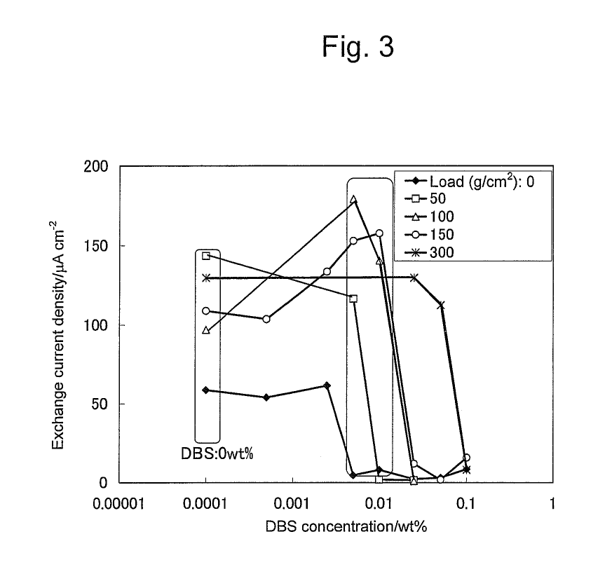

### BEST MODE FOR CARRYING OUT THE INVENTION

Hereinafter, the present invention will be described in detail with reference to Examples.

Polishing conditions and production of colloidal silica used in Examples 1 to 12 and Comparative Examples 1 to 6 were performed as follows.

### (Production of Colloidal Silica)

The colloidal silica having an average particle diameter of 40 nm was produced by hydrolysis in an aqueous ammonium solution of tetraethoxysilane.

### (Polishing Conditions)

There was used a silicon substrate on which a copper foil having a thickness of 1 μm was formed as a base substance. There was used a foaming polyurethane resin having independent air bubbles as a polishing pad. The relative velocity between the base substance and the polishing pad was set to 36 m/min. The load was set to 300 g/cm².

### (Polishing Evaluation)

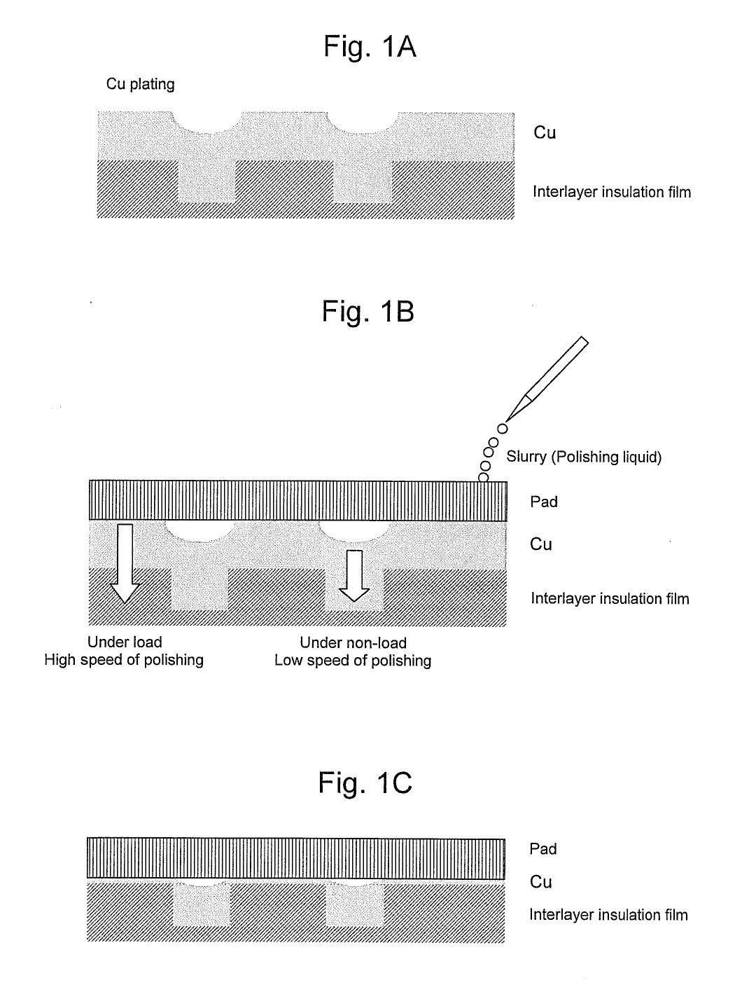

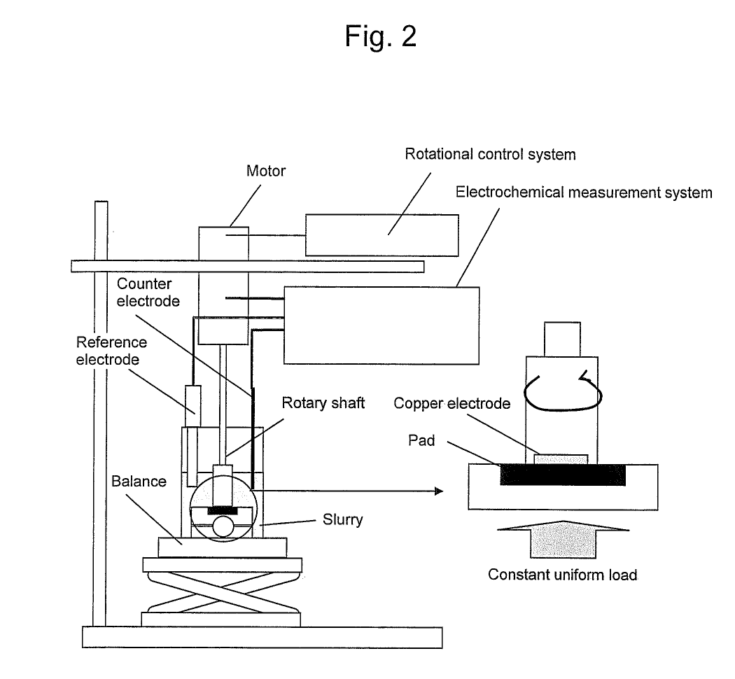

Exchange current densities under load and under non-load were determined by Tafel measurement using a device shown in FIG. 2 and an electrochemical technique. The polishing speed due to CMP was calculated by converting a difference between film thicknesses of copper foil before or after the CMP from electrical resistance values. After forming a groove having a depth of 0.5 μm on an insulation film and embedding copper in the groove by a known sputter method and electroplating method (FIG. 1A), the CMP was carried out. Referring to the dishing amount, the decrease amount of a wiring metal part to an insulation part was calculated from a surface shape of a stripe pattern part in which wiring metal parts having a width of 100 μm and insulation parts having a width of 100 μm were alternately arranged by a sending pin type level difference meter.

Herein, referring to the polishing speed evaluation, good means 3000 Å/min or more; average means 1000 to 2000 Å/min; and poor means 1000 Å/min or less. Referring to the dishing evaluation, very good means 100 Å or less; good means 1000 Å or less; average means 1000 to 2000 Å; and poor means 2000 Å or more.

### Example 1

As a result of carrying out CMP using a slurry which contains malic acid of 0.01 M as a copper solubilizer, potassium nitrate of 0.1 M as a solubility accelerator, hydrogen peroxide of 2.0 M as an oxidizer, benzotriazole of 0.025 M as a protective film forming agent, potassium dodecylbenzene sulfonate of 0.0003 M as a surfactant, and 1.0 wt % of colloidal silica of 40 nm as an abrasive grain and has a pH of 2.0 (adjusted by H₂SO₄), as shown in Table 1, good results could be obtained in both polishing speed and dishing. Exchange current densities in this slurry under non-load and under load, respectively, are shown in Table 1. The ratio of the exchange current densities is 1409, and a difference therebetween is very large.

### Example 2

As a result of carrying out CMP using salicylaldoxime of 0.03 M in place of the benzotriazole as the protective film forming agent used in the Example 1 and cetyltrimethylammonium bromide having the same concentration as that of the potassium dodecylbenzene sulfonate in place of the potassium dodecylbenzene sulfonate as the surfactant, as shown in Table 1, good results could be obtained in both polishing speed and dishing. Exchange current densities in this slurry under non-load and under load, respectively, are shown in Table 1. The ratio of the exchange current densities is 482, and a difference therebetween is very large.

### Example 3

As a result of carrying out CMP using potassium sulfate having the same concentration as that of the potassium nitrate in place of the potassium nitrate as the solubility accelerator used in the Example 1, and setting the concentration of the benzotriazole as the protective film forming agent to double (0.05 M), as shown in Table 1, good results could be obtained in both polishing speed and dishing. Exchange current densities in this slurry under non-load and under load, respectively, are shown in Table 1. The ratio of the exchange current densities is 63, and a difference therebetween is very large.

### Example 4

As a result of carrying out CMP using anthranilic acid of 0.02 M in place of the benzotriazole as the protective film forming agent used in the Example 1 and sodium oleate of 0.00015 M in place of the potassium dodecylbenzene sulfonate as the surfactant, as shown in Table 1, good results could be obtained in both polishing speed and dishing. Exchange current densities in this slurry under non-load and under load, respectively, are shown in Table 1. The ratio of the exchange current densities is 2600, and a difference therebetween is very large.

### Example 5

As a result of carrying out CMP using ammonium nitrate of 0.20 M in place of the potassium nitrate as the solubility accelerator used in the Example 1 and anthranilic acid of 0.02 M in place of the benzotriazole as the protective film forming agent, as shown in Table 1, good results could be obtained in both polishing speed and dishing. Exchange current densities in this slurry under non-load and under load, respectively, are shown in Table 1. The ratio of the exchange current densities is 1500, and a difference therebetween is very large.

### Example 6

As a result of carrying out CMP using aluminium nitrate of 0.15 M in place of the potassium nitrate as the solubility accelerator used in the Example 1 and oxine of 0.01M in place of the benzotriazole as the protective film forming agent, as shown in Table 1, good results could be obtained in both polishing speed and dishing. Exchange current densities in this slurry under non-load and under load, respectively, are shown in Table 1. The ratio of the exchange current densities is 694, and a difference therebetween is very large.

### Example 7

As a result of carrying out CMP using succinic acid having the same concentration of that of the malic acid in place of the malic acid as copper solubilizer used in the Example 1, aluminium nitrate of 0.15M in place of the potassium nitrate as the solubility accelerator, anthranilic acid of 0.02 M in place of the benzotriazole as the protective film forming agent and sodium dodecyl sulfate of 0.015 M in place of the potassium dodecylbenzene sulfonate as the surfactant, as shown in Table 1, good results could be obtained in both polishing speed and dishing. Exchange current densities in this slurry under non-load and under load, respectively, are shown in Table 1. The ratio of the exchange current densities is 162, and a difference therebetween is very large.

### Example 8

As a result of carrying out CMP using oxalic acid having the same concentration as that of the malic acid in place of the malic acid as copper solubilizer used in the Example 1, potassium thiocyanate of 0.1M in place of the potassium nitrate as the solubility accelerator, anthranilic acid of 0.02M in place of the benzotriazole as the protective film forming agent and sodium dodecyl sulfate of 0.015 M in place of the potassium dodecylbenzene sulfonate as the surfactant, as shown in Table 1, good results could be obtained in both polishing speed and dishing. Exchange current densities in this slurry under non-load and under load, respectively, are shown in Table 1. The ratio of the exchange current densities is 115, and a difference therebetween is very large.

### Example 9

As a result of carrying out CMP using iron nitrate of 0.015 M in place of the hydrogen peroxide as the oxidizer used in the Example 1, setting the concentration of the benzotriazole as the protective film forming agent to double (0.05 M), and using cetyltrimethylammonium of 0.0003 M in place of the dodecylbenzene sulfonic acid as the surfactant, as shown in Table 1, good results could be obtained in both polishing speed and dishing. Exchange current densities in this slurry under non-load and under load, respectively, are shown in Table 1. The ratio of the exchange current densities is 127, and a difference therebetween is very large.

### Example 10

As a result of carrying out CMP using ammonium perchlorate of 0.1M in place of the potassium nitrate as the solubility accelerator used in the Example 1, ammonium persulfate in place of the hydrogen peroxide as the oxidizer, and salicylaldoxime of 0.03 M in place of the benzotriazole as the protective film forming agent, as shown in Table 1, good results could be obtained in both polishing speed and dishing. Exchange current densities in this slurry under non-load and under load, respectively, are shown in Table 1. The ratio of the exchange current densities is 340, and a difference therebetween is very large.

### Example 11

As a result of carrying out CMP using phosphoric acid having the same concentration as that of the malic acid in place of the malic acid as copper solubilizer used in the Example 1, as shown in Table 1, good results could be obtained in both polishing speed and dishing. Exchange current densities in this slurry under non-load and under load, respectively, are shown in Table 1. The ratio of the exchange current densities is 143, and a difference therebetween is very large.

### Example 12

As a result of carrying out CMP further adding polyacrylic acid of 0.4 wt % as an aqueous solution polymer to the polishing slurry of the Example 1, good results could be obtained in both polishing speed and dishing. Particularly, the dishing was 100 Å or less, and could be further reduced as compared with the case of the Example 1. Exchange current densities in this slurry under non-load and under load, respectively, are shown in Table 1. The ratio of the exchange current densities is 3750, and a difference therebetween is very large.

### Example 13

As a result of carrying out CMP using polyvinyl alcohol of 0.4 wt % in place of the polyacrylic acid of the aqueous solution polymer in the polishing slurry of the Example 12 and sodium dodecyl sulfate of 0.015 M in place of the potassium dodecylbenzene sulfonate as the surfactant, good results could be obtained in both polishing speed and dishing. Particularly, the dishing was 100 Å or less, and could be further reduced as compared with the case of the Example 1. Exchange current densities in this slurry under non-load and under load, respectively, are shown in Table 1. The ratio of the exchange current densities is 1694, and a difference therebetween is very large.

TABLE 1

| | | | | | | | Corrosion inhibitor | | | |
|---|---|---|---|---|---|---|---|---|---|---|
| | | | | | | | (Protective film forming | | | |
| | Copper solubilizer | | Solubility accelerator | | Oxidizer | | agent) | | Surfactant | |
| | | Concen- | | Concen- | | Concen- | | Concen- | | Concen- |
| | Compound | tration | Compound | tration | Compound | tration | Compound | tration | | tration |
| | name | (M) | name | (M) | name | (M) | name | (M) | Compound name | (M) |
| Ex. 1 | Malic acid | 0.01 | KNO₃ | 0.10 | H₂O₂ | 2.00 | BTA | 0.025 | Potassium | 0.0003 |
| | | | | | | | | | dodecylbenzene | |
| | | | | | | | | | sulfonate | |
| Ex. 2 | Malic acid | 0.01 | KNO₃ | 0.10 | H₂O₂ | 2.00 | Salicylal- | 0.03 | Cetyltrimethyl- | 0.0003 |
| | | | | | | | doxime | | ammonium | |
| | | | | | | | | | bromide | |
| Ex. 3 | Malic acid | 0.01 | K₂SO₄ | 0.10 | H₂O₂ | 2.00 | BTA | 0.050 | Potassium | 0.0001 |
| | | | | | | | | | dodecylbenzene | |
| | | | | | | | | | sulfonate | |
| Ex. 4 | Malic acid | 0.01 | NH₄NO₃ | 0.20 | H₂O₂ | 2.00 | Anthranilic | 0.02 | Sodium oleate | 0.00015 |
| | | | | | | | acid | | | |
| Ex. 5 | Malic acid | 0.01 | NH₄NO₃ | 0.20 | H₂O₂ | 2.00 | Anthranilic | 0.02 | Potassium | 0.0003 |
| | | | | | | | acid | | dodecylbenzene | |
| | | | | | | | | | sulfonate | |
| Ex. 6 | Malic acid | 0.01 | Al(NO₃)₃ | 0.15 | H₂O₂ | 2.00 | Oxine | 0.01 | Potassium | 0.0003 |
| | | | | | | | | | dodecylbenzene | |
| | | | | | | | | | sulfonate | |
| Ex. 7 | Succinic | 0.01 | Al(NO₃)₃ | 0.15 | H₂O₂ | 2.00 | Anthranilic | 0.02 | Sodium dodecyl | 0.0015 |
| | acid | | | | | | acid | | sulfate | |
| Ex. 8 | Oxalic acid | 0.01 | KSCN | 0.10 | H₂O₂ | 2.00 | Anthranilic | 0.02 | Sodium dodecyl | 0.0015 |
| | | | | | | | acid | | sulfate | |
| Ex. 9 | Malic acid | 0.01 | KNO₃ | 0.10 | Fe(NO₃)₃ | 0.015 | BTA | 0.050 | Cetyltrimethyl- | 0.0003 |
| | | | | | | | | | ammonium | |
| | | | | | | | | | bromide | |
| Ex. 10 | Malic acid | 0.01 | NH₄ClO₄ | 0.10 | K₂S₂O₈ | 0.10 | Salicylal- | 0.03 | Potassium | 0.0003 |
| | | | | | | | doxime | | dodecylbenzene | |
| | | | | | | | | | sulfonate | |
| Ex. 11 | Phosphoric | 0.01 | KNO₃ | 0.10 | H₂O₂ | 2.00 | BTA | 0.025 | Potassium | 0.0003 |
| | acid | | | | | | | | dodecylbenzene | |
| | | | | | | | | | sulfonate | |
| Ex. 12 | Malic acid | 0.01 | KNO₃ | 0.10 | H₂O₂ | 2.00 | BTA | 0.025 | Potassium | 0.0003 |
| | | | | | | | | | dodecylbenzene | |
| | | | | | | | | | sulfonate | |
| Ex. 13 | Malic acid | 0.01 | KNO₃ | 0.10 | H₂O₂ | 2.00 | BTA | 0.025 | Sodium dodecyl | 0.015 |
| | | | | | | | | | suliate | |

| | Water-soluble polymer | | | Abrasive grains | | | | Exchange current density | |
|---|---|---|---|---|---|---|---|---|---|
| | | Concen- | | | Concen- | Polishing | | (μA/cm²) | |
| | Compound | tration | | | tration | speed | Dishing | Under | |
| | name | (wt %) | pH | Type | (wt %) | evaluation | evaluation | non-load | Underload |
| Ex. 1 | — | — | 2.00 | Colloidal | 1.00 | G | G | 0.66 | 930 |
| | | | | silica | | | | | |
| | | | | 40 nm | | | | | |
| Ex. 2 | — | — | 2.00 | Colloidal | 1.00 | G | G | 2.0 | 965 |
| | | | | silica | | | | | |
| | | | | 40 nm | | | | | |
| Ex. 3 | — | — | 2.00 | Colloidal | 1.00 | G | G | 10 | 630 |
| | | | | silica | | | | | |
| | | | | 40 nm | | | | | |
| Ex. 4 | — | — | 2.00 | Colloidal | 1.00 | G | G | 0.2 | 520 |
| | | | | silica | | | | | |
| | | | | 40 nm | | | | | |
| Ex. 5 | — | — | 2.00 | Colloidal | 1.00 | G | G | 0.8 | 1200 |
| | | | | silica | | | | | |
| | | | | 40 nm | | | | | |
| Ex. 6 | — | — | 2.00 | Colloidal | 1.00 | G | G | 1.8 | 1250 |
| | | | | silica | | | | | |
| | | | | 40 nm | | | | | |
| Ex. 7 | — | — | 2.00 | Colloidal | 1.00 | G | G | 5.5 | 890 |
| | | | | silica | | | | | |
| | | | | 40 nm | | | | | |
| Ex. 8 | — | — | 2.00 | Colloidal | 1.00 | G | G | 8.5 | 980 |
| | | | | silica | | | | | |
| | | | | 40 nm | | | | | |
| Ex. 9 | — | — | 2.00 | Colloidal | 1.00 | G | G | 8.5 | 1080 |
| | | | | silica | | | | | |
| | | | | 40 nm | | | | | |
| Ex. 10 | — | — | 2.00 | Colloidal | 1.00 | G | G | 2.5 | 850 |
| | | | | silica | | | | | |
| | | | | 40 nm | | | | | |
| Ex. 11 | — | — | 2.00 | Colloidal | 1.00 | G | G | 3.5 | 500 |
| | | | | silica | | | | | |
| | | | | 40 nm | | | | | |
| Ex. 12 | Polyacrylic | 0.4 | 2.00 | Colloidal | 1.00 | G | VG | 0.32 | 1200 |
| | acid | | | silica | | | | | |
| | | | | 40 nm | | | | | |
| Ex. 13 | Polyvinyl | 0.4 | 2.00 | Colloidal | 1.00 | G | VG | 0.62 | 1050 |
| | alcohol | | | silica | | | | | |
| | | | | 40 nm | | | | | |

### Comparative Example 1

As a result of carrying out CMP using a slurry which contains malic acid of 0.01 M as a copper solubilizer, potassium nitrate of 0.1 M as a solubility accelerator, hydrogen peroxide of 2.0 M as an oxidizer, benzotriazole of 0.025 M as a protective film forming agent, and 1.0 wt % of colloidal silica of 40 nm as an abrasive grain and has a pH of 2.0 (adjusted by H₂SO₄), as shown in the following Table 2, the demand for polishing speed could be satisfied. However, an excellent result could not be obtained in the dishing. Exchange current densities in this slurry under non-load and under load, respectively, are shown in Table 2. The ratio of the exchange current densities is 15, and the difference therebetween is not large. This Comparative Example is obtained by extracting the surfactant from the components of the Example 1. As compared with the result of the Example 1, the exchange current density under non-load is large.

### Comparative Example 2

As a result of carrying out CMP using a slurry obtained by extracting the solubility accelerator, the protective film forming agent and the surfactant from the components of the Example 1, neither polishing speed nor dishing could satisfy the requirement. Exchange current densities in the slurry under non-load and under load, respectively, are shown in Table 2. The ratio of the exchange current densities is 0.26, and the exchange current density under non-load becomes larger than the exchange current density under load, bringing about a result contrary to the case of each of the Examples.

### Comparative Example 3

As a result of carrying out CMP setting the concentration of copper solubilizer to 20 times of that of the Example 1 and using a slurry into which the solubility accelerator, the protective film forming agent and the surfactant are not added, neither polishing speed nor dishing could satisfy the requirement. Exchange current densities in the slurry under non-load and under load, respectively, are shown in Table 2. The ratio of the exchange current densities is 0.09, and the exchange current density under non-load becomes larger than the exchange current density under load, bringing about a result contrary to the case of each of the Examples. The exchange current density under load cannot be increased simply by increasing the concentration of copper solubilizer. The large exchange current density under non-load is based on no addition of the protective film forming agent and surfactant.

### Comparative Example 4

As a result of carrying out CMP in a slurry of which a pH is increased to 3.5 from 2.0 in the components of the Example 1, neither polishing speed nor dishing could satisfy the requirement. Exchange current densities in the slurry under non-load and under load, respectively, are shown in Table 2. The ratio of the exchange current densities is 19, and is smaller than that of each of the Examples. Although the exchange current density under non-load is not changed so much, the exchange current density under load is largely reduced.

### Comparative Example 5

As a result of carrying out CMP in a slurry obtained by removing the potassium nitrate as the solubility accelerator in the components of the Example 1, neither polishing speed nor dishing could satisfy the requirement. Exchange current densities in the slurry under non-load and under load, respectively, are shown in Table 2. The ratio of the exchange current densities is 30, and is smaller than that of each of the Examples.

### Comparative Example 6

As a result of carrying out CMP in a slurry which is obtained by removing the potassium nitrate as the solubility accelerator in the components of the Example 1 and of which a pH is increased to 3.5 from 2.0, neither polishing speed nor dishing could satisfy the requirement. Exchange current densities in the slurry under non-load and under load, respectively, are shown in Table 2. The ratio of the exchange current densities is 10, and is smaller than that of each of the Examples.

### Comparative Example 7

As a result of carrying out CMP in a slurry which is obtained by replacing KNO₃ as the solubility accelerator with NH₄NO₃ and in which the hydrogen peroxide as the oxidizer is further removed in the components of the Example 1, neither polishing speed nor dishing could satisfy the requirement. Exchange current densities in the slurry under non-load and under load, respectively, are shown in Table 2. The ratio of the exchange current densities is 33, and is smaller than that of each of the Examples.

### Comparative Example 8

CMP was carried out using 0.10 M of ammonium persulfate as the solubility accelerator to the slurry in the state of the Comparative Example 5. As a result, neither polishing speed nor dishing could satisfy the requirement. Exchange current densities in the slurry under non-load and under load, respectively, are shown in Table 2. The ratio of the exchange current densities is 24, and is smaller than that of each of the Examples.

TABLE 2

| | | | | | | | Corrosion inhibitor | | | |
|---|---|---|---|---|---|---|---|---|---|---|
| | | | | | | | (Protective film forming | | | |
| | Copper solubilizer | | Solubility accelerator | | Oxidizer | | agent) | | Surfactant | |
| | | Concen- | | Concen- | | Concen- | | Concen- | | Concen- |
| | Compound | tration | Compound | tration | Compound | tration | Compound | tration | Compound | tration |
| | name | (M) | name | (M) | name | (M) | name | (M) | name | (M) |
| Comp. | Malic acid | 0.01 | KNO₃ | 0.10 | H₂O₂ | 2.00 | BTA | 0.025 | — | — |
| Ex. 1 | | | | | | | | | | |
| Comp. | Malic acid | 0.01 | — | — | H₂O₂ | 2.00 | — | — | — | — |
| Ex. 2 | | | | | | | | | | |
| Comp. | Malic acid | 0.20 | — | — | H₂O₂ | 2.00 | — | — | — | — |
| Ex. 3 | | | | | | | | | | |
| Comp. | Malic acid | 0.01 | KNO₃ | 0.10 | H₂O₂ | 2.00 | BTA | 0.025 | Potassium | 0.0003 |
| Ex. 4 | | | | | | | | | dodecylbenzene | |
| | | | | | | | | | sulfonate | |
| Comp. | Malic acid | 0.01 | — | — | H₂O₂ | 2.00 | BTA | 0.025 | Potassium | 0.0003 |
| Ex. 5 | | | | | | | | | dodecylbenzene | |
| | | | | | | | | | sulfonate | |
| Comp. | Malic acid | 0.01 | — | — | H₂O₂ | 2.00 | BTA | 0.025 | Potassium | 0.0003 |
| Ex. 6 | | | | | | | | | dodecylbenzene | |
| | | | | | | | | | sulfonate | |
| Comp. | Malic acid | 0.01 | NH₄NO₃ | 0.20 | — | — | BTA | 0.025 | Potassium | 0.0003 |
| Ex 7 | | | | | | | | | dodecylbenzene | |
| | | | | | | | | | sulfonate | |
| Comp. | Malic acid | 0.01 | K₂S₂O₈ | 0.10 | H₂O₂ | 2.00 | BTA | 0.025 | Potassium | 0.0003 |
| Ex. 8 | | | | | | | | | dodecylbenzene | |
| | | | | | | | | | sulfonate | |

| | Water-soluble polymer | | | Abrasive grains | | | | Exchange current density | |
|---|---|---|---|---|---|---|---|---|---|
| | | Concen- | | | Concen- | Polishing | | (μA/cm²) | |
| | Compound | tration | | | tration | speed | Dishing | Under | |
| | name | (wt %) | pH | Type | (wt %) | (A/min) | evaluation | non-load | Underload |
| Comp. | — | — | 2.00 | Colloidal silica | 1.00 | G | A | 65 | 950 |
| Ex. 1 | | | | 40 nm | | | | | |
| Comp. | — | — | 2.00 | Colloidal silica | 1.00 | A | P | 1035 | 272 |
| Ex. 2 | | | | 40 nm | | | | | |
| Comp. | — | — | 2.00 | Colloidal silica | 1.00 | A | P | 3852 | 346 |
| Ex. 3 | | | | 40 nm | | | | | |
| Comp. | — | — | 3.50 | Colloidal silica | 1.00 | A | A | 5.0 | 95 |
| Ex. 4 | | | | 40 nm | | | | | |
| Comp. | — | — | 2.00 | Colloidal silica | 1.00 | A | A | 8.0 | 240 |
| Ex. 5 | | | | 40 nm | | | | | |
| Comp. | — | — | 3.50 | Colloidal silica | 1.00 | P | A | 7.0 | 70 |
| Ex. 6 | | | | 40 nm | | | | | |
| Comp. | — | — | 3.50 | Colloidal silica | 1.00 | P | P | 0.6 | 20 |
| Ex. 7 | | | | 40 nm | | | | | |
| Comp. | — | — | 2.00 | Colloidal silica | 1.00 | A | A | 15.0 | 360 |
| Ex. 8 | | | | 40 nm | | | | | |

As shown in the Examples and Comparative Examples shown in Tables 1 and 2, when the exchange current density under load is large and the exchange current density under non-load is small, high-speed polishing as well as low dishing can be accomplished. The optimal numerical value under non-load is 10 μA/cm² or less, and is 5 Å/min or less in terms of the etching rate. The exchange current density under load is required to be at least 500 μA/cm² or more.

The following components (1) to (5) are required for a composition for attaining the high-speed polishing as well as low dishing: (1) a copper solubilizer as an organic acid such as malic acid and citric acid and an inorganic acid such as phosphoric acid; (2) a copper solubility accelerator which is an inorganic salt represented by nitrate, sulfate, thiocyanic acid salt, ammonium salt and oxo-acid salt and which is a compound of which an oxidation potential of an anionic species is highly positive compared with an oxidation potential of water and the anionic species is stable at the oxidation potential of the water, and which is an inorganic salt represented by nitrate, sulfate, thiocyanic acid salt, ammonium salt and oxo-acid salt and which is a compound of which an oxidation potential of an anionic species is highly positive compared with an oxidation potential of water and the anionic species is stable at the oxidation potential of the water; (3) a protective film forming agent represented by BTA and quinaldinic acid; (4) a surfactant represented by potassium dodecylbenzene sulfonate; and (5) an oxidizer represented by hydrogen peroxide and ammonium persulfate. The mole number of the total of the ions in these components is required to be at least 100 mmol or more. The sum total of the ions is important, and even if the concentration of the malic acid which is not totally dissociated is increased as shown in the Comparative Example 3, the exchange current density under load is not dramatically increased. When the surfactant is not added, as shown in the Comparative Example 1, the high-speed polishing can be performed. However, the exchange current density under non-load is increased, and the dishing is increased. When the solubility accelerator is not added, as shown in the Comparative Example 5, the exchange current density under load is reduced, and the polishing speed is reduced. When the solubility accelerator, the corrosion inhibitor and the surfactant are not added, as shown in the Comparative Example 2, the exchange current density under non-load is greatly increased and the dishing is greatly increased while the exchange current density under load is reduced and the polishing speed is reduced. When the pH is increased, as shown in the Comparative Example 4, the exchange current density under load is reduced, and the polishing speed is reduced. When the hydrogen peroxide as the oxidizer is removed, as shown in the Comparative Example 7, even if NH₄NO₃ as the solubility accelerator is added, the exchange current density under load is reduced, and the polishing speed is reduced. When the solubility accelerator is not added and the pH is further increased, as shown in the Comparative Example 6, the exchange current density under load is reduced, and the polishing speed is reduced. When the ammonium persulfate is added to the solubility accelerator and the hydrogen peroxide is used as the oxidizer as shown in the Comparative Example 8, as described above, the ammonium persulfate does not play a role of the solubility accelerator, and thereby the exchange current density under load is not greatly increased. However, since the ammonium persulfate has a function as the oxidizer, the ammonium persulfate increases the exchange current densities under non-load and under load to some extent.

### INDUSTRIAL APPLICABILITY

The present invention can accomplish the high CMP polishing speed and the dishing suppression simultaneously and form the highly reliable wiring.

1. A CMP method for copper using a polishing liquid, comprising polishing a copper surface with the polishing liquid, characterized in that the polishing liquid comprises at least one inorganic salt in a concentration of 0.01 M or more, which has an anionic species having an oxidation potential more positive than that of water, the anionic species being stable at the oxidation potential of water, a compound capable of forming an insoluble complex with copper, and a surfactant, wherein the concentration ratio of the compound capable of forming an insoluble complex with copper to the surfactant is 1/0.0001 to 1/0.4 by mol, or 1/0.0004 to 1/1.0 by weight, and wherein the polishing liquid comprises a solution at a pH of 3.0 or less.

2. The CMP method for copper according to claim 1, wherein the polishing liquid further comprises a water-soluble polymer.

3. The CMP method for copper according to claim 1, wherein the inorganic salt has a cationic species of at least one selected from the group consisting of potassium, sodium, ammonium, iron and aluminum.

4. The CMP method for copper according to claim 1, wherein the compound capable of forming an insoluble complex with copper is at least one selected from the group consisting of benzotriazole, cupferron, salicylaldoxime, cysteine, aminobenzaldehyde, haloacetic acid, quinaldinic acid, benzoimidazole, benzoin oxime, anthranilic acid, nitrosonaphthol and oxine.

5. The CMP method for copper according to claim 1, wherein the surfactant is dodecylbenzene sulfonic acid, potassium dodecyl sulfate, cetyltrimethylammonium bromide or sodium oleate.

6. The CMP method for copper according to claim 2, wherein the water-soluble polymer is at least one selected from the group consisting of polyacrylic acid, polyvinylpyrrolidone, polyacrylamide, polyvinyl alcohol and poly-(4-vinylpyridine).

7. The CMP method for copper according to claim 1, wherein the polishing liquid comprises a solution having a total ion concentration of 100 mM or more.

8. The CMP method for copper according to claim 1, wherein Cu²⁺ ions exist in a stable region of a pH-potential diagram.

9. The CMP method for copper according to claim 1, wherein the polishing liquid can etch a rotating surface for CMP at an etching rate of 5 Å/min or less under non-load, and 500 Å/min or more under load.

10. The CMP method for copper according to claim 1, wherein said at least one inorganic salt is selected from the group consisting of nitrates, sulfates, thiocyanates and oxo-acid salts.

11. The CMP method for copper according to claim 1, wherein said at least one inorganic salt is selected from the group consisting of potassium nitrate, ammonium nitrate, aluminum nitrate, potassium thiocyanate, potassium sulfate, ammonium perchlorate, potassium perchlorate and aluminum perchlorate.
